(19) United States
(12) Patent Application Publication
(10) Pub. No.: US 2008/0160698 A1
(43) Pub. Date: Jul. 3, 2008

(54) METHOD FOR FABRICATING A SEMICONDUCTOR DEVICE

(75) Inventor: Ki-Lyoung LEE, Ichon-shi (KR)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Hynix Semiconductor Inc., Icheon-si (KR)

(21) Appl. No.: 11/752,873

(22) Filed: May 23, 2007

(30) Foreign Application Priority Data
Dec. 27, 2006 (KR) 10-2006-0134295

(51) Int. Cl. H01L 21/336

(52) U.S. Cl. 438/270; 257/E21.41

(57) ABSTRACT

A method for fabricating a semiconductor device includes forming an isolation structure using a pad insulation layer for device isolation. A hard mask pattern forming a plurality of recesses is formed over an upper portion of a substrate including the pad insulation layer. The pad insulation layer and the substrate are etched using the hard mask pattern as a mask to form a certain recess pattern. A cell channel ion implantation process is performed using a patterned pad insulation layer as an ion implantation barrier to form a plurality of local channel regions. A gate pattern is then formed over the certain recess pattern.

### CROSS-REFERENCE TO RELATED APPLICATIONS

The present invention claims priority of Korean patent application number 10-2006-0134295, filed on Dec. 27, 2006, which is incorporated by reference in its entirety.

### BACKGROUND OF THE INVENTION

The present invention relates to a method for fabricating a semiconductor device, and more particularly, to a method for fabricating a semiconductor device having a bulb-shaped recess gate.

The current large integration scale of semiconductor devices has caused a channel length to be decreased, thereby generating a short channel effect. Thus, a device property may be degraded. However, this limitation may not be solved using a typical planar type transistor.

A recess gate process capable of increasing the channel length of a cell transistor has been suggested. The recess gate process forms a gate after etching an active region of a substrate to form a transistor. If the recess gate process is applied, properties such as drain-induced barrier lowering, a breakdown voltage between a drain and a source, and a junction leakage may be improved. Accordingly, a refresh property of the device may be improved as well.

However, as the large integration scale of the semiconductor device has been continuously required, a design rule of the device is decreased to lower than about 60 nm. As a result, although the recess gate process is used, a threshold voltage margin and a refresh property reach a limitation. In order to overcome the above limitation, a bulb-shaped recess gate process has been recently developed. In the bulb-shaped recess gate process, a recess is formed by performing an etching process twice. Particularly, while performing the second etching process, a bottom portion of the recess is formed in a sphere shape. Thus, the channel length may be increased compared to the typical recess gate process, thereby improving the refresh property.

FIGS. 1A to 1F illustrate a method for fabricating a typical bulb-shaped recess gate. Particularly; a cell channel implantation process to be performed after a recess is formed is exemplified.

As shown in FIG. 1A, a patterned pad oxide layer 12 and a patterned pad nitride layer 13 are formed over a patterned substrate 11. A trench for an isolation structure is formed in a portion of the patterned substrate 11. In more detail, a pad oxide layer and a pad nitride layer are formed over a substrate. Then, the pad oxide layer and the pad nitride layer are patterned to have a certain pattern. Exposed portions of the substrate are etched using the certain pattern as a mask to form the trench.

An insulation layer is formed over an entire surface of the patterned substrate 11 including the trench. A chemical mechanical polishing process is performed to fill the insulation layer into the trench. As a result, an isolation structure 14 is formed.

As shown in FIG. 1B, the patterned pad nitride layer 13 is removed, but the patterned pad oxide layer 12 remains. The patterned pad oxide layer 12 serves as a sacrificial oxide layer when forming subsequent recesses.

As shown in FIG. 1C, a hard mask layer 15 serving as an etch barrier while forming the subsequent recesses is formed over the resultant structure including the patterned pad oxide layer 12. The hard mask layer 15 may be formed by stacking an amorphous carbon layer 15A and a silicon oxynitride (SiON) layer 15B. A photoresist pattern 16 is formed over an upper portion of the hard mask layer 15 to define regions where the subsequent recesses are to be formed.

As shown in FIG. 1D, the hard mask layer 15 is etched using the photoresist pattern 16 as a mask to form a hard mask pattern (not shown). Then, the photoresist pattern 16 is removed.

The patterned pad oxide layer 12 is etched using the hard mask pattern (not shown) as an etch barrier. A plurality of first patterned pad oxide layers 12A are obtained. Then, portions of the patterned substrate 11 exposed by the first patterned pad oxide layers 12A are etched. As a result, a plurality of recesses each formed in a vertical profile, i.e., neck patterns 110A, are obtained. A reference numeral 11A identifies a first patterned substrate.

The hard mask pattern (not shown) is removed. Then, a spacer insulation layer 17 serving as an etch barrier when forming subsequent bulb patterns is formed over an entire surface of the first patterned substrate 11A including the neck patterns 110A.

As shown in FIG. 1E, the spacer insulation layer 17 is subjected to an etch back process. An isotropic etching process is performed to bottom portions of the neck patterns 110A exposed by the etch back process of the spacer insulation layer 17. As a result, a plurality of recesses each having a sphere profile, i.e., bulb patterns 110B, are formed. A plurality of bulb-shaped recesses 110 are formed with the neck patterns 110A and the bulb patterns 110B. A reference numeral 11B identifies a second patterned substrate.

A threshold voltage screen oxide layer (not shown) is formed and then a cell channel ion implantation process is performed to control a threshold voltage. As a result, a doping region 120 is formed in a certain portion of the second patterned substrate 11B.

As shown in FIG. 1F, a cleaning process is performed to remove the patterned pad oxide layer 12A and etch residue. A gate oxide layer (not shown) is formed over an entire surface of the second patterned substrate 11B including the bulb-shaped recesses 110, and a plurality of gate patterns 18 are formed. First portions of the gate patterns 18 fill the bulb-shaped recesses 17, and second portions of the gate patterns 18 are projected over the second patterned substrate 11B. Each of the gate patterns 18 is formed by stacking a polysilicon layer 18A, a tungsten silicide layer 18B, and a gate hard mask nitride layer 18C. A source/drain implantation process is performed to form junction regions 130. A fabrication process of the semiconductor device having the typical bulb-shaped recesses is then complete.

FIGS. 2A to 2F illustrate a method for fabricating a typical bulb-shaped recess gate. Particularly, a cell channel ion implantation process performed before a recess is formed is exemplified. Hereinafter, steps shown in FIGS. 2A to 2F, which are the same as those shown in FIGS. 1A to 1F, will be briefly explained herein with reference to FIGS. 1A to 1F.

As shown in FIG. 2A, a patterned pad oxide layer 22 and a patterned pad nitride layer 23 are formed over a patterned substrate 21. An isolation structure 24 is formed in the patterned substrate 21 (see FIG. 1A).

As shown in FIG. 2B, the patterned pad nitride layer 23 is removed and then the patterned pad oxide layer 22 is removed via a wet cleaning process prior to a formation of a threshold voltage screen oxide layer (not shown). A threshold voltage screen oxidation process is performed on the patterned substrate 21 exposed by the removal of the patterned pad oxide layer 22. Then, a cell channel ion implantation process is performed to control a threshold voltage. As a result, a doping region 210 is formed in a certain portion of the patterned substrate 21. A sacrificial oxide layer 25 is formed to form subsequent recesses over the patterned substrate 21.

As shown in FIG. 2C, a hard mask layer 26 is formed over the sacrificial oxide layer 25. The hard mask layer 26 includes an amorphous carbon layer 26A and a silicon oxynitride layer 26B. A photoresist pattern 27 defining regions where recesses are to be formed is formed over the hard mask layer 26 (see FIG. 1C).

As shown in FIG. 2D, the hard mask layer 26, the sacrificial oxide layer 25, and the patterned substrate 21 are etched using the photoresist pattern 27 as a mask to form neck patterns 220A. A hard mask pattern (not shown), a patterned sacrificial oxide layer 25A, and a first patterned substrate 21A are obtained. Then, a spacer insulation layer 28 is formed to form subsequent bulb patterns (see FIG. 1D).

As shown in FIG. 2E, bottom portions of the first patterned substrate 21A exposed by the neck patterns 220A are subjected to an isotropic etching process using the spacer insulation layer 28. As a result, bulb patterns 220B are formed, and a second patterned substrate 21B is obtained. A plurality of bulb-shaped recesses including the bulb patterns 220B and the neck patterns 220A are formed (see FIG. 1E).

As shown in FIG. 2F, a cleaning process is performed and then, a gate oxide layer (not shown) is formed over an entire surface of the second patterned substrate 21B including the bulb-shaped recesses 220. A plurality of gate patterns 29 are formed. Each gate pattern 29 includes a polysilicon layer 29A, a tungsten silicide layer 29B, and a gate hard mask nitride layer 29C that are formed. Then, a plurality of junction regions 230 are formed via a source/drain ion implantation process (see FIG. 1F).

Referring to FIGS. 1A to 1F and FIGS. 2A to 2F, the methods for fabricating the semiconductor device having the bulb-shaped recess gates have two limitations.

If distribution of the doping regions 120 and 210 formed via the cell channel ion implantation process is examined, impurities unnecessarily exist up to portions other than channel regions. Accordingly, portions A and B (see FIGS. 1F and 2F) may be generated where the doping regions 120 and 210 respectively overlap with the junction regions 130 and 230 formed via the subsequent source/drain ion implantation process. Due to the overlapping portions A and B an electric field may be increased, thereby increasing a junction leakage. As a result, a refresh property of the device may be degraded.

Thicknesses of the spacer insulation layers 17 and 28 used as a barrier during etching to form the bulb patterns 110B and 220B are small. However, an etch rate of the isotropic etching process is relatively excessive to the thicknesses of the spacer insulation layers 17 and 28. Accordingly, upper portions of the first patterned substrates 11A and 21A may be attacked during the etching process. The attacks which may be caused during the etching process cannot be reduced only by the patterned pad oxide layer 12 or the sacrificial oxide layer 25 disposed underneath the spacer insulation layers 17 and 28.

### SUMMARY OF THE INVENTION

Embodiments of the present invention are directed toward providing a method for fabricating a semiconductor device. The method prevents a doping region formed via a cell channel ion implantation process from overlapping with a junction region formed via a subsequent source/drain ion implantation process. The method also prevents an attack generated on an upper portion of a substrate during an isotropic etching process to form a bulb pattern of a bulb-shaped recess using a pad nitride layer used during a device isolation process. Thus, a refresh property of the device is improved and a process is stabilized.

In accordance with one aspect of the present invention, a method for fabricating a semiconductor device includes forming an isolation structure using a pad insulation layer for device isolation. A hard mask pattern forming a plurality of recesses is formed over an upper portion of a substrate including the pad insulation layer. The pad insulation layer and the substrate are etched using the hard mask pattern as a mask to form a certain recess pattern. A cell channel ion implantation process is performed using a patterned pad insulation layer as an ion implantation barrier to form a plurality of local channel regions. A gate pattern is then formed over the certain recess pattern.

In accordance with another aspect of the present invention, a method for fabricating a semiconductor device includes forming an isolation structure in a substrate using a pad insulation layer for device isolation. A hard mask pattern forming a plurality of recesses is formed over an upper portion of the substrate including the pad insulation layer. The pad insulation layer and the substrate are etched using the hard mask pattern as a mask to form a plurality of neck patterns of bulb-shaped recesses. A plurality of spacers are formed over sidewalls of the neck patterns. An isotropic etching process is performed on the substrate below the neck patterns using the patterned pad insulation layer and the spacers as etch barriers to form a plurality of bulb patterns of the bulb-shaped recesses. A gate pattern is then formed over the bulb-shaped recesses including the neck patterns and the bulb patterns.

### BRIEF DESCRIPTION OF THE DRAWINGS

FIGS. 1A to 1F illustrate a method for fabricating a semiconductor device having a typical bulb-shaped recess gate.

FIGS. 2A to 2F illustrate a method for fabricating a semiconductor device having another typical bulb-shaped recess gate.

FIGS. 3A to 3F illustrate a method for fabricating a semiconductor device having a bulb-shaped recess gate pattern in accordance with an embodiment of the present invention.

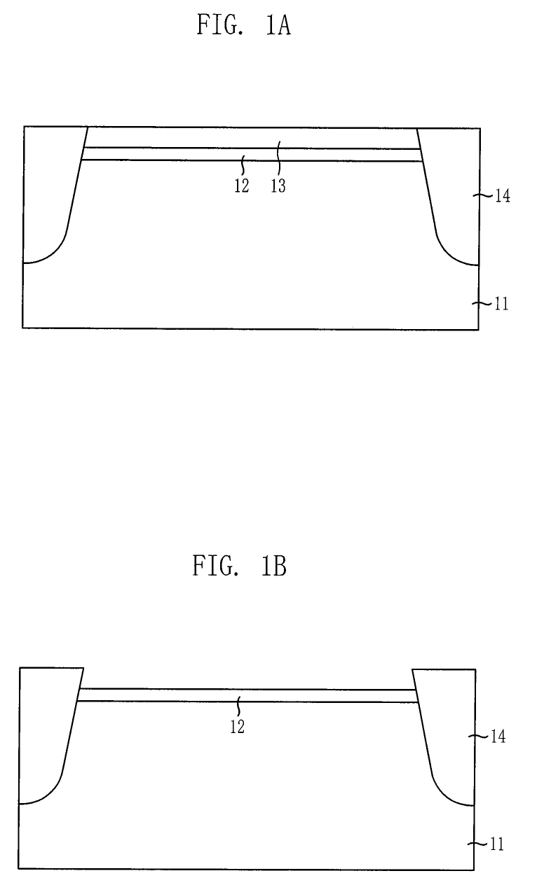

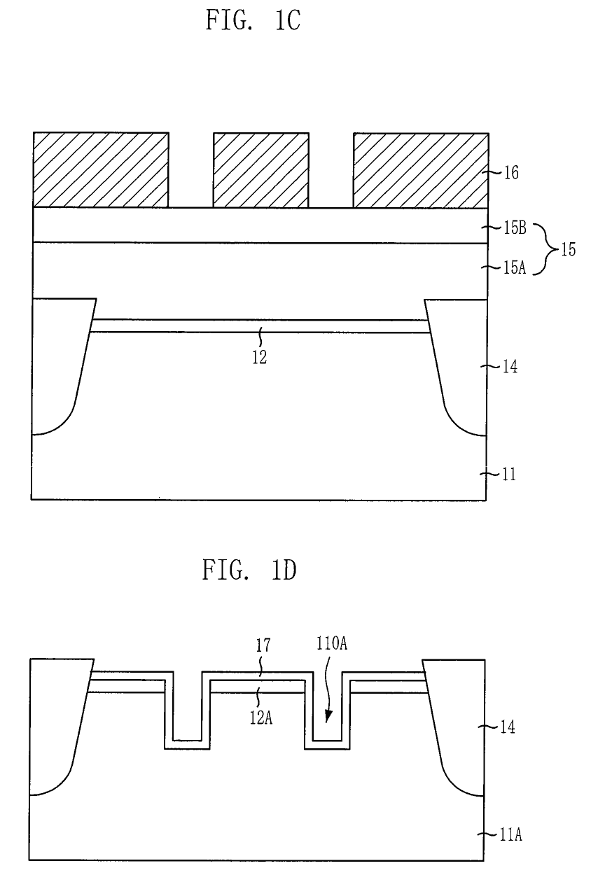

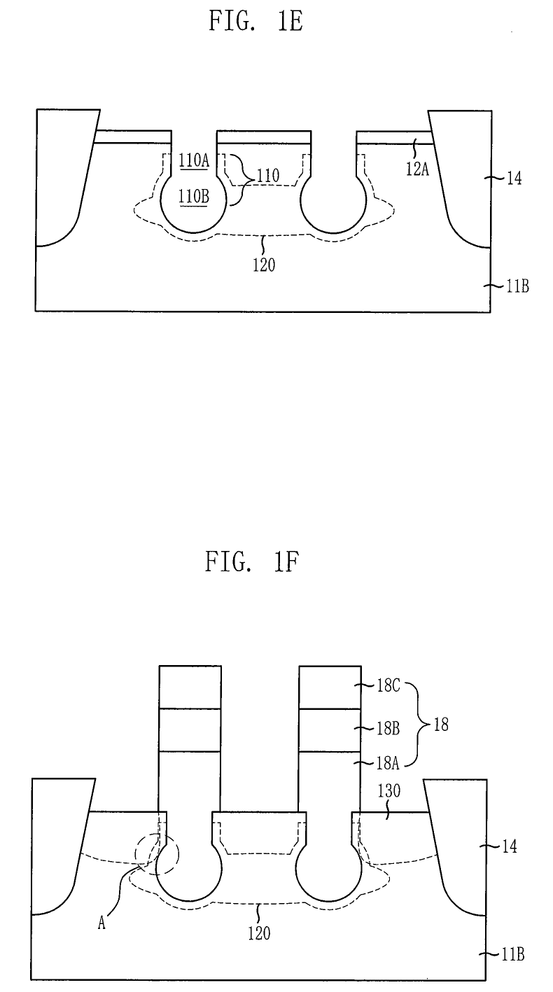

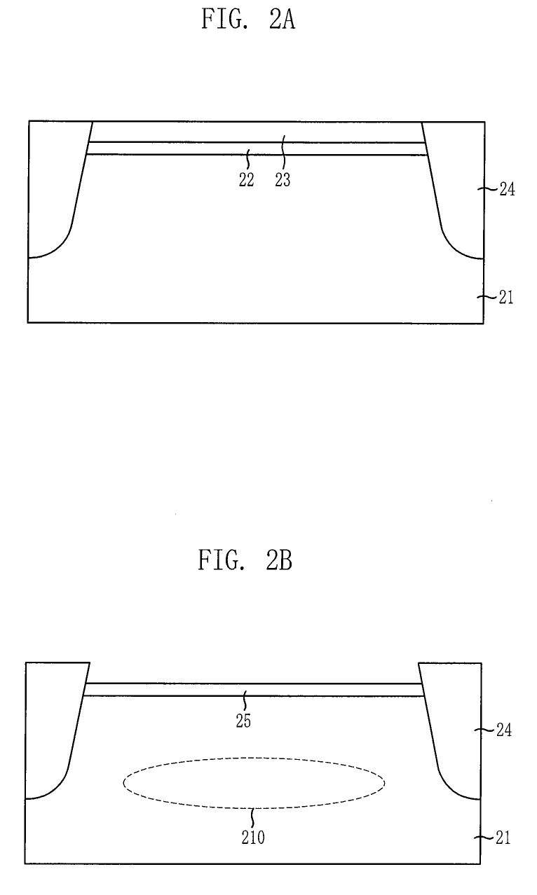

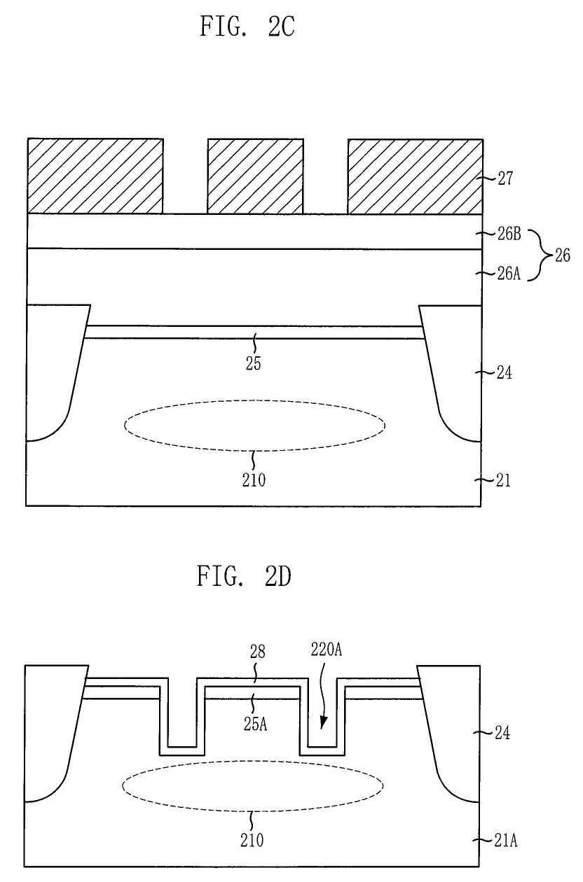

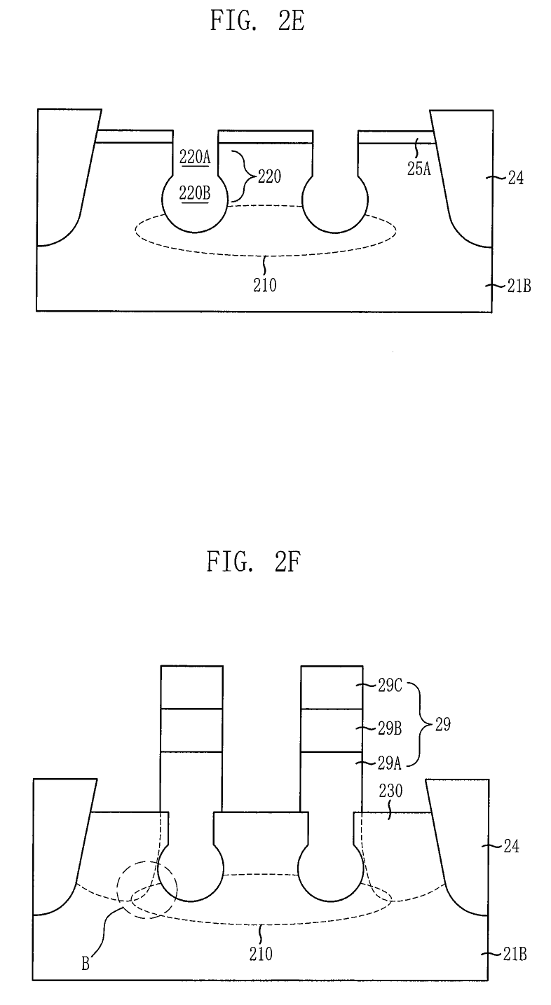

### DESCRIPTION OF SPECIFIC EMBODIMENTS

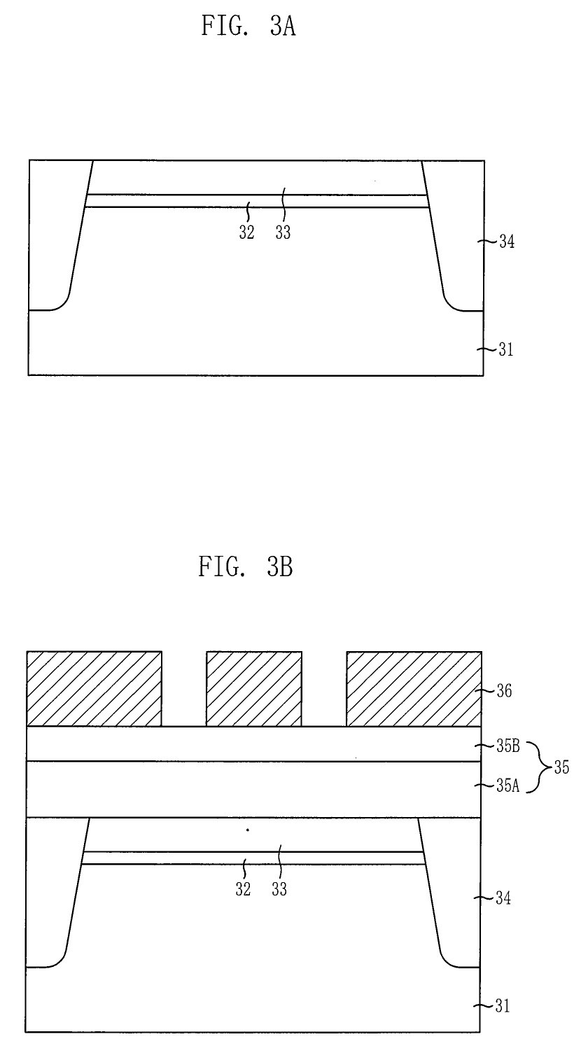

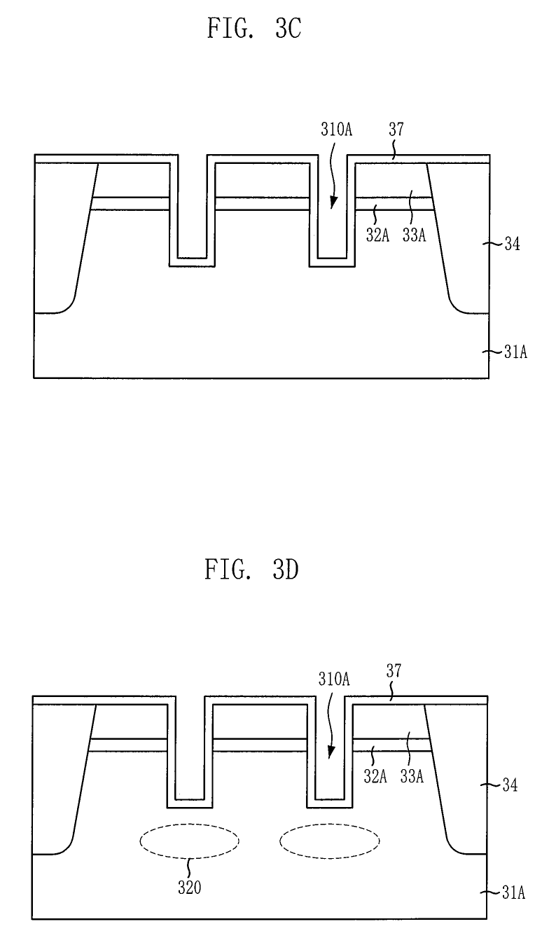

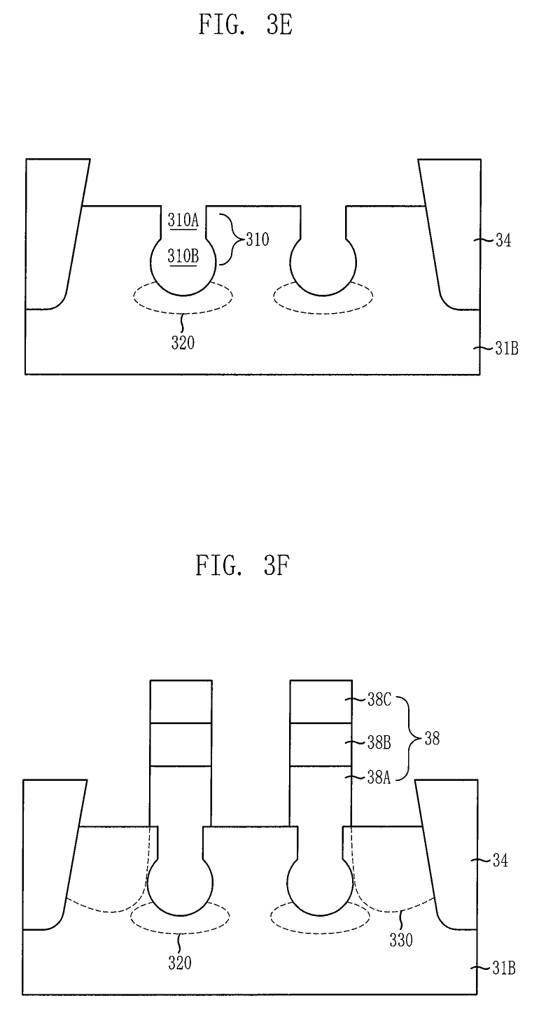

FIGS. 3A to 3F illustrate a method for fabricating a semiconductor device having a bulb-shaped recess gate in accordance with an embodiment of the present invention. As shown in FIG. 3A, a patterned pad oxide layer 32 and a patterned pad nitride layer 33 are formed over a patterned substrate 31. A trench for device isolation is formed in the patterned substrate 31. The patterned pad oxide layer 32 and the patterned nitride layer 33 serve as pad insulation layers during device isolation. In more detail, a pad oxide layer and a pad nitride layer are formed over the patterned substrate 31. Then, the pad oxide layer and the pad nitride layer are patterned to a certain pattern. Exposed portions of a substrate are etched using the certain pattern as a mask to obtain the trench.

An insulation layer is formed over an entire surface of the patterned substrate 31 including the trench. Then, a planarization process is performed until the patterned pad nitride layer 33 is exposed. As a result, the insulation layer fills the trench to form an isolation structure 34. The planarization process can be performed via a chemical mechanical polishing process.

The patterned pad nitride layer 33 is not removed after the formation of the isolation structure 34, but is used when forming subsequent recesses and performing a subsequent cell channel ion implantation process. Particularly, the patterned pad nitride layer 33 serves as an ion implantation barrier of the subsequent cell channel ion implantation. Thus, the patterned pad nitride layer 33 can have a high density, e.g., a density of about 3.2 g/cm³.

As shown in FIG. 3B, a hard mask layer 35 serving as an etch barrier when forming the subsequent recesses is formed over an upper portion of the above resultant structure including the patterned pad nitride layer 33. For instance, the hard mask layer 35 includes an amorphous carbon layer 35A and a silicon oxynitride (SiON) layer 35B. However, instead of using the hard mask layer 35 including the stack structure of the amorphous carbon layer 35A and the SiON layer 35B, a hard mask layer including a polysilicon layer or a hard mask layer including a nitride layer can be used.

A photoresist pattern 36 defining regions where the subsequent recesses are to be formed is formed over an upper portion of the SiON layer 35B. An anti-reflective coating layer (not shown) for preventing a reflection during a photo-exposure process may be disposed underneath the photoresist pattern 36.

As shown in FIG. 3C, the SiON layer 35B and the amorphous carbon layer 35A are etched using the photoresist pattern 36 as a mask to form a hard mask pattern (not shown) including a patterned SiON layer (not shown) and a patterned amorphous carbon layer (not shown). Then, the photoresist pattern 36 is removed.

The patterned pad nitride layer 33 and the patterned pad oxide layer 32 are etched using the hard mask pattern (not shown) as an etch barrier. A first patterned pad nitride layer 33A and a first patterned pad oxide layer 32A are obtained. Portions of the patterned substrate 31 exposed by the etching of the patterned pad nitride layer 33 and the patterned pad oxide layer 32 are etched to form a plurality of neck patterns 310A of subsequent bulb-shaped recesses. The neck patterns 310A are formed in vertical profiles. The neck patterns 310A can be formed to thicknesses ranging from about 400 Å to about 1000 Å. Herein, a further patterned substrate is referred to as a first patterned substrate identified with a reference numeral 31A.

The hard mask pattern (not shown) is removed. A spacer insulation layer 37 serving as an etch barrier when forming subsequent bulb patterns is formed over an entire surface of the first patterned substrate 31A including the neck patterns 310A. The spacer insulation layer 37 includes a hot temperature oxide (HTO) layer. The spacer insulation layer 37 is formed to a thickness ranging from about 30 Å to about 70 Å.

As shown in FIG. 3D, a threshold voltage screen oxide layer (not shown) is formed and then a channel ion implantation process is performed to control a threshold voltage. The first patterned pad nitride layer 33A which is remaining serves as a barrier of an ion implantation. Thus, ions cannot be implanted into portions other than channel regions, i.e., storage node contact regions and a bit line contact region. Accordingly, doping regions formed via the cell channel ion implantation are defined only within channel regions, and these channel regions are called local channel regions 320. During the cell channel ion implantation, a tilt and a rotation are controlled to increase a concentration of an impurity of the local channel regions 320. As a result, a threshold voltage of the channel regions can be increased. For instance, the cell channel ion implantation process is performed at a tilt of about 4° to 8° with a rotation of about 0° to 180°.

As shown in FIG. 3E, the spacer insulation layer 37 is subjected to an etch back process. Due to the etch back process, spacers (not shown) protecting sidewalls of the neck patterns 310A are formed, and portions of the first patterned substrate 31A underneath the neck patterns 310A are exposed. Then, the exposed portions of the first patterned substrate 31A underneath the neck patterns 310A are subjected to an isotropic etching process using the spacers (not shown) and the first patterned nitride layer 33A as a barrier. As a result, bulb patterns 310B are formed in sphere profiles. A plurality of bulb-shaped recesses 310 including the neck patterns 310A and the bulb patterns 310B are formed. The bulb patterns 310B are formed to thicknesses ranging from about 400 Å to about 1000 Å. A reference numeral 31B identifies a second patterned substrate.

As described above, the spacer insulation layer 37 is not only formed to a small thickness ranging from about 30 Å to about 70 Å but is also subjected to the etch back process. Accordingly, the spacer insulation layer 37 cannot shield an upper portion of the first patterned substrate 31A from attacks generated during the isotropic etching process. Instead of the spacer insulation layer 37, the first patterned pad nitride layer 33A shields the upper portion of the first patterned substrate 31A from the attacks.

A wet cleaning process is performed to remove the first patterned pad nitride layer 33A, the first patterned pad oxide layer 32A, and etch residue. As a result, the local channel regions 320 exist only underneath the bulb-shaped recesses 310.

As shown in FIG. 3F, a gate oxide layer (not shown) is formed over an entire surface of the second patterned substrate 31B including the bulb-shaped recesses 310. A plurality of gate patterns 38, of which first portions fill the bulb-shaped recesses 310 and second portions are projected over the second patterned substrate 31B, are formed. For instance, each of the gate patterns 38 is formed by stacking a patterned polysilicon layer 38A, a patterned tungsten silicide layer 38B and a patterned mask nitride layer 38C. In more detail, a polysilicon layer, a tungsten silicide layer and a gate hard mask nitride layer are stacked. Then, a mask and etching process is performed thereto to obtain the gate patterns 38 including the patterned polysilicon layer 38A, the patterned tungsten silicide layer 38B, and the patterned gate hard mask nitride layer 38C. A source/drain ion implantation process is performed to form a plurality of junction regions 330.

According to the embodiment of the present invention, the junction regions 330 do not overlap with the local channel regions 320. Accordingly, an electric field and a junction leakage can be reduced, thereby improving a refresh property of a device. In addition, during the etching of the bulb-shaped recesses 310, the first patterned pad nitride layer 33A prevents attacks on the upper portion of the first patterned substrate 31A. As a result, the bulb-shaped recess gate process can be stably performed.

According to the embodiment of the present invention, the pad nitride layer for device isolation is used as the barrier of the cell channel ion implantation and as the etch barrier when forming the bulb patterns of the bulb-shaped recesses. However, the present invention is not confined to this embodiment. Also, the pad nitride layer for the isolation structure used as the barrier of the cell channel ion implantation or used as the etch barrier when forming the bulb-shaped recesses can be included in the scope of the claims of the present invention. Furthermore, the pad nitride layer for the device isolation can be used as the ion implantation barrier to form the local channel regions underneath other types of recesses in addition to the bulb-shaped recesses.

According to the method for fabricating the semiconductor device of the present invention, the pad nitride layer used during the device isolation process remains. Thus, the doping region formed via the cell channel ion implantation process does not overlap with the junction region formed via the subsequent source/drain ion implantation process. Furthermore, when performing an isotropic etching process to form the bulb pattern of the bulb-shaped recess, the pad nitride layer shields the upper portion of the substrate from attacks. As a result, the refresh property of the device can be improved and the process can be stabilized.

While the present invention has been described with respect to the specific embodiments, it will be apparent to those skilled in the art that various changes and modifications may be made without departing from the spirit and scope of the invention as defined in the following claims.

What is claimed is:

1. A method for fabricating a semiconductor device, comprising:
forming an isolation structure using a pad insulation layer for device isolation;
forming a hard mask pattern to form a plurality of recesses over an upper portion of a substrate including the pad insulation layer;
etching the pad insulation layer and the substrate using the hard mask pattern as a mask to form a certain recess pattern;
performing a cell channel ion implantation process using a patterned pad insulation layer as an ion implantation barrier to form a plurality of local channel regions; and
forming a gate pattern over the certain recess pattern.

2. The method of claim 1, wherein forming the isolation structure includes:
forming a pad oxide layer and a pad nitride layer over the substrate;
patterning the pad oxide layer and the pad nitride layer to a certain pattern;
etching the substrate exposed due to the patterning of the pad oxide layer and the pad nitride layer to form a trench for device isolation;
forming an insulation layer over a resultant surface profile of the substrate including the trench; and
planarizing the insulation layer until the patterned pad nitride layer is exposed.

3. The method of claim 1, wherein the pad insulation layer includes a nitride layer.

4. The method of claim 1, wherein the hard mask pattern is formed by stacking an amorphous carbon layer and a silicon oxynitride (SiON) layer.

5. The method of claim 1, wherein the hard mask pattern includes a polysilicon layer or a nitride layer.

6. The method of claim 1, wherein the cell ion implantation process is performed at a tilt ranging from about 4° to about 8°, and at a rotation ranging from about 0° to about 180°.

7. The method of claim 1, wherein the gate pattern is formed by stacking a polysilicon layer, a tungsten silicide layer, and a gate hard mask nitride layer.

8. The method of claim 1, further comprising performing a source/drain ion implantation process to form a plurality of junction regions, wherein the source/drain ion implantation process is performed after the gate pattern is formed.

9. A method for fabricating a semiconductor device, comprising:
forming an isolation structure in a substrate using a pad insulation layer for device isolation;
forming a hard mask pattern to form a plurality of recesses over an upper portion of the substrate including the pad insulation layer;
etching the pad insulation layer and the substrate using the hard mask pattern as a mask to form a plurality of neck patterns of bulb-shaped recesses;
forming a plurality of spacers over sidewalls of the neck patterns;
performing an isotropic etching process on the substrate below the neck patterns using the patterned pad insulation layer and the spacers as etch barriers to form a plurality of bulb patterns of the bulb-shaped recesses; and
forming a gate pattern over the bulb-shaped recesses including the neck patterns and the bulb patterns.

10. The method of claim 9, wherein forming the isolation structure includes:
forming a pad oxide layer and a pad nitride layer over the substrate;
patterning the pad oxide layer and the pad nitride layer to a certain pattern;
etching the substrate exposed due to the patterning of the pad oxide layer and the pad nitride layer to form a trench for device isolation;
forming an insulation layer over a resultant surface profile of the substrate including the trench; and
planarizing the insulation layer until a patterned pad nitride layer is exposed.

11. The method of claim 9, wherein the pad insulation layer includes a nitride layer.

12. The method of claim 9, wherein the hard mask pattern is formed by stacking an amorphous carbon layer and a SiON layer.

13. The method of claim 9, wherein the hard mask pattern includes a polysilicon layer or a nitride layer.

14. The method of claim 9, wherein the neck patterns of the bulb-shaped recesses are formed to thicknesses ranging from about 400 Å to about 1000 Å.

15. The method of claim 9, wherein the bulb patterns of the bulb-shaped recesses are formed to thicknesses ranging from about 400 Å to about 1000 Å.

16. The method of claim 9, wherein forming the spacers over sidewalls of the neck pattern includes:
forming an insulation layer to form the spacers over the substrate including the patterned pad insulation layer and the neck patterns; and
performing an etch back process to the insulation layer.

17. The method of claim 16, wherein the insulation layer includes a hot temperature oxide layer and is formed to a thickness ranging from about 30 Å to about 70 Å.

18. The method of claim 9, wherein the gate pattern is formed by stacking a polysilicon layer, a tungsten silicide layer, and a gate hard mask nitride layer.

19. The method of claim 9, further comprising performing a cell channel ion implantation process using the patterned pad insulation layer as an ion implantation barrier to form a plurality of local channel regions, wherein the cell channel ion implantation process is performed after forming the neck patterns of the bulb-shaped recesses.

20. The method of claim 19, wherein the cell channel ion implantation process is performed at a tilt ranging from about 4° to about 8° and at a rotation ranging from about 0° to about 180°.

21. The method of claim 19, further comprising performing a source/drain ion implantation process to form a plurality of junction regions, wherein the source/drain ion implantation process is performed after forming the gate pattern.
